(19) United States
(12) Patent Application Publication
(10) Pub. No.: US 2024/0282733 A1
(43) Pub. Date: Aug. 22, 2024

(54) SEMICONDUCTOR DEVICE WITH DELAMINATION REDUCTION MECHANISM AND METHODS FOR MANUFACTURING THE SAME

(71) Applicant: Micron Technology, Inc., Boise, ID (US)

(72) Inventors: Jungbae Lee, Taichung (TW); Bong Woo Choi, Singapore (SG)

(21) Appl. No.: 18/410,769

(22) Filed: Jan. 11, 2024

Related U.S. Application Data
(60) Provisional application No. 63/446,287, filed on Feb. 16, 2023.

(51) Int. Cl. H01L 23/00; H01L 23/498

(52) U.S. Cl. CPC H01L 24/10; H01L 23/498; H01L 24/05; H01L 24/11; H01L 24/13; H01L 24/16; H01L 24/81; H01L 24/32; H01L 24/73; H01L 2224/05568; H01L 2224/05647; H01L 2224/10152; H01L 2224/11013; H01L 2224/13021; H01L 2224/13111; H01L 2224/13113; H01L 2224/13116; H01L 2224/13139; H01L 2224/13147; H01L 2224/16227; H01L 2224/32225; H01L 2224/73204; H01L 2224/81007; H01L 2224/81192; H01L 2224/81815

(57) ABSTRACT

Methods, apparatuses, and systems related to a device having a delamination reduction mechanism disposed between a solder resist layer and a contact pad of a substrate. The substrate may include a solder opening in the solder resist layer over the contact pad. The delamination reduction mechanism may have bonding strengths relative to the solder resist layer and the contact pad that are greater than a bonding strength associated with a direct contact between the solder resist layer and the contact pad.

### CROSS-REFERENCE TO RELATED APPLICATION(S)

The present application claims priority to U.S. Provisional Patent Application No. 63/446,287, filed Feb. 16, 2023, the disclosure of which is incorporated herein by reference in its entirety.

### TECHNICAL FIELD

The disclosed embodiments relate to devices, and, in particular, to semiconductor devices with delamination reduction mechanism and methods for manufacturing the same.

### BACKGROUND

The current trend in semiconductor fabrication is to manufacture smaller and faster devices with a higher density of components for computers, cell phones, pagers, personal digital assistants, and many other products. However, decrease in circuit size can lead to other unanticipated issues. For example, decreasing the footprint of each semiconductor die and/or increasing the signal density can decrease the pitch or the separation distance between signal pins. Such decreased pitch can lead to structural failure of the overall device during manufacturing process.

### BRIEF DESCRIPTION OF THE DRAWINGS

FIG. 1A a cross-sectional view of a semiconductor device assembly.

FIG. 1B illustrates a detailed view of a portion 1B-1B of FIG. 1A.

FIG. 2A a cross-sectional view of a semiconductor device assembly in accordance with an embodiment of the present technology.

FIG. 2B illustrates a detailed view of a portion 2B-2B of FIG. 2 in accordance with an embodiment of the present technology.

FIG. 3—FIG. 9 are example processing stages in manufacturing the semiconductor device assembly of FIG. 2A or a portion thereof in accordance with an embodiment of the present technology.

FIG. 10 is a flow diagram illustrating an example method of manufacturing a semiconductor device or a portion thereof in accordance with an embodiment of the present technology.

FIG. 11 is a schematic view of a system that includes a semiconductor device in accordance with an embodiment of the present technology.

### DETAILED DESCRIPTION

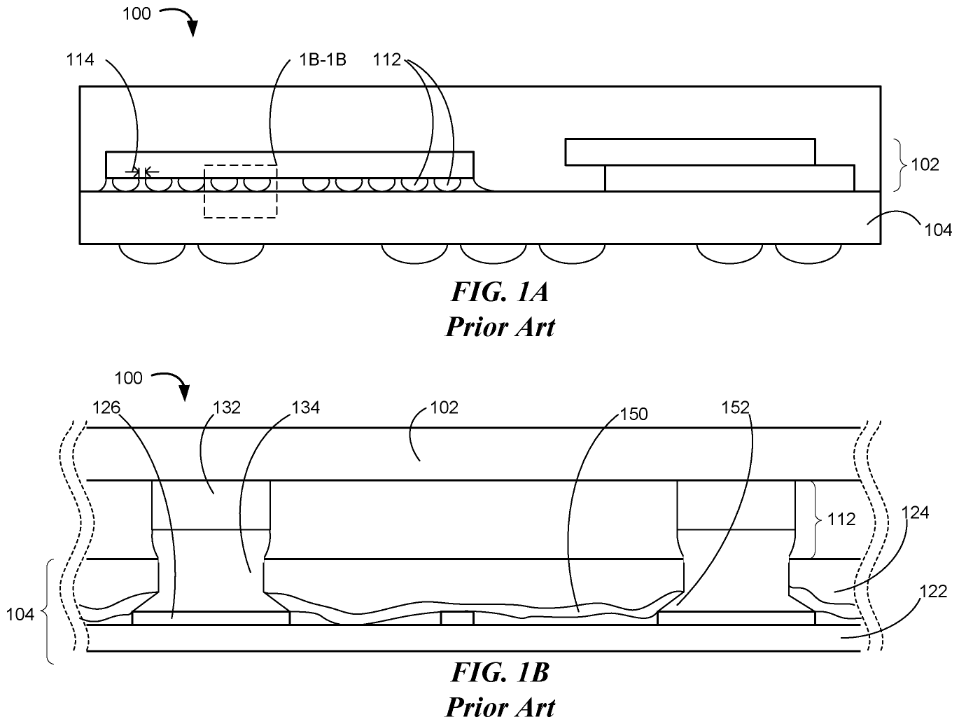

To illustrate the structural failures caused by decreases in the pitch, FIG. 1 is a cross-sectional view of a semiconductor device assembly 100. The semiconductor assembly 100 can include one or more semiconductor devices 102 (e.g., semiconductor dies and/or packages) mounted on a top surface of a substrate 104 (e.g., a printed circuit board (PCB)). In some embodiments, an underfill (e.g., protective paste, resin, adhesive, and/or the like) may be disposed between the one or more semiconductor devices 102 and the top surface of the substrate 104. The assembly 100 can include an encapsulant over the top surface of the substrate 104 and the semiconductor devices 102. The encapsulant (e.g., resin material) can encase and protect the one or more semiconductor devices 102 from the external environment.

The assembly 100 can have external connectors (e.g., solder, pads, etc.) on a bottom surface of the substrate 104 for communicating with external circuits, devices, or systems. Internally, the one or more semiconductor devices 102 can be electrically coupled to the substrate 104 using internal or die connectors 112. Some examples of the internal connectors 112 can include bond wires, solder, pads, pillars, or a combination thereof. For each of the one or more semiconductor devices 102, the corresponding set of internal connectors 112 can be arranged according to a connector pitch 114. The connector pitch 114 can correspond to an actual separation distance between adjacently arranged connectors or a minimum/maximum threshold thereof.

The exchanged signals and voltages can be routed through and/or across the substrate 104 using one or more redistribution layers (RDLs). The RDLs can include contact pads, traces, wires, vias, signal planes, or a combination thereof.

In manufacturing the assembly 100, the substrate 104 and the semiconductor devices 102 can be manufactured separately and then attached together. For example, the semiconductor devices 102 can be attached to or mounted over the substrate 104 by reflowing solder in the internal connectors 112. After attaching, the attached structure can undergo multiple reflows or intentional environmental conditions (e.g., increased temperatures), such as for flowing and solidifying the underfill, for reliability testing, or the like. In conventional designs, the processes occurring after the attaching process can cause delamination (e.g., separations or cracks between layers) within the substrate 104. The delamination can occur when solder resist/mask layer in the substrate 104 separates away from one or more portions (e.g., the RDL) underneath. In addition to the structural failure, the delamination can cause electrical shorts, such as by allowing the solder to flow laterally and form unintended electrical connections. Such failures are occurring more frequently as the connector pitch 114 is reduced to accommodate additional signals, smaller chip designs, faster signal performance, and other increasing performance demands.

To further illustrate the delamination failure, FIG. 1B illustrates a detailed view of a portion 1B-1B of FIG. 1. As shown in the detailed view, the substrate 104 includes a reference layer 122 (e.g., a prepreg layer) and a solder resist layer 124 that covers the RDL attached over the reference layer 122. The RDL can include contact pads 126 (e.g., copper pad) configured to contact the internal connectors 112 for providing electrical connections to the corresponding dies 102.

The internal connectors 112 can each include (1) a solder 134 over and contacting the contact pad 126 and (2) a pillar 132 (e.g., a copper extension) that extends from the die and directly contacts the solder 134. As described above, the substrate 104 can be manufactured with the solder 134 over the contact pads 126 and placed within corresponding openings in the solder resist layer 124, and the semiconductor devices 102 can be manufactured separately with the pillars 134. During the assembly, the pillars 132 can be aligned overlapping the corresponding solder 134 and the solder 134 can be reflowed. The internal connectors 112 can be formed based on reflowing the solder 134, thereby electrically connecting and affixing the pillars 132 to the solder 134 and to the substrate 104 overall.

The attached structure may be exposed to additional temperature changes that result in multiple reflows. Each temperature change and the corresponding solder reflow can cause expansion of contraction of the various components within the substrate 104. The different materials in the various components can have different expansion factors (e.g., different amounts of changes in the size of the component, different rate of change, or other changes in response to temperature). Such changes can cause a delamination 150 in or between the reference layer 122 and/or the solder resist layer 124.

Additionally or alternatively, the delamination 140 can be caused by mask undercuts 152 formed during manufacturing of the substrate 104. The mask undercuts 152 can include a widening of the openings over the contact pads 126 at portions closest to the contact pads 126. In other words, the openings for the solder 134 can form undercuts in the solder resist layer 124, and the solder 134 can be wider at the bottom than at top portions of the corresponding openings. The mask undercuts 152 can be formed as a natural byproduct during an etching process (e.g., chemical or dry etch) used to form the openings. The laterally extending shape of the mask undercuts 152 and the additional weight/pressure in the solder provided by the attached die can provide a lifting force on the solder resist layer 124 and away from reference layer 122. The lifting force is opposed by the adhesive force between the solder resist layer 124 and reference layer 122, which is often lessened at locations where the copper (e.g., internal traces) in the RDL directly contacts the solder resist layer 124. As such, decreases in the connector pitch 114 and/or increases in the complexity of the RDL for accommodating the increasing performance demands lead to increased occurrences of the delamination 150.

As described in greater detail below, the technology disclosed herein relates to a semiconductor device assembly having a delamination reduction mechanism. In some embodiments, the semiconductor device assembly can include one or more semiconductor devices having a predetermined application (e.g., wireless communication), a communication speed exceeding a minimum threshold, and/or a connector pitch that is below/narrower than a minimum separation distance (e.g., 500 μm, 300 μm or less). To accommodate such semiconductor devices, the delamination reduction mechanism can include an adhesion promoter (e.g., HexaMethylDiSilazane (HMDS)) disposed between one or more components or layers within a substrate that is attached to the semiconductor devices. For example, the delamination reduction mechanism can include the adhesion promoter disposed between an RDL (e.g., copper structures thereof) and a solder resist layer. In some embodiments, the adhesion promoter can be applied (1) below and contacting the solder resist layer and (2) over the RDL and a reference layer (e.g., a prepreg layer).

The delamination reduction mechanism can be formed during manufacturing of a substrate. For example, the adhesion promoter can be applied (1) after patterning the RDL over the reference layer and/or (2) before solder resist printing. Accordingly, the adhesion promoter can prevent formation of the mask undercuts 152 of FIG. 1B and increase the adhesion strength between the components in the RDL (e.g., the copper structures) and the solder resist layer. Thus, the delamination reduction mechanism reduce the occurrence of the delamination 150 of FIG. 1B and the corresponding structural/electrical failures.

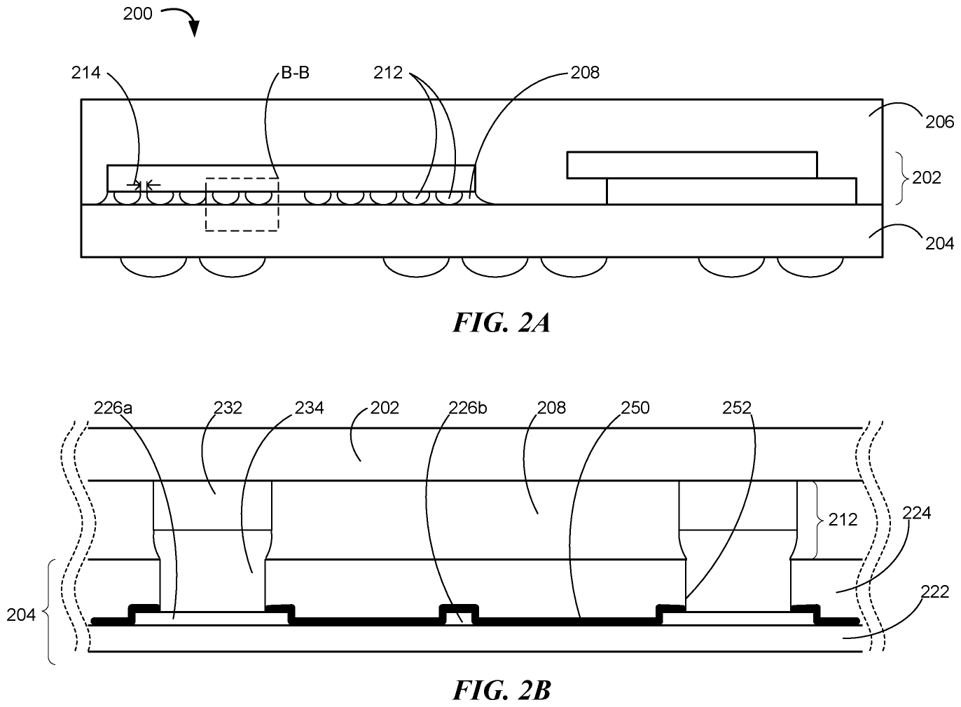

FIG. 2A a cross-sectional view of a semiconductor device assembly 200 in accordance with an embodiment of the present technology. FIG. 2B illustrates a detailed view of a portion 2B-2B of FIG. 2 in accordance with an embodiment of the present technology. As described in detail below the assembly 200 can include the delamination reduction mechanism.

Referring now to FIGS. 2A and 2B together, the assembly 200 can include one or more semiconductor devices 202 (e.g., semiconductor dies and/or packages) mounted on a top surface of a substrate 204 (e.g., a printed circuit board (PCB)). In some embodiments, an underfill 208 (e.g., protective paste, resin, adhesive, and/or the like) may be disposed between the one or more semiconductor devices 202 and the top surface of the substrate 204. The assembly 200 can include an encapsulant 206 (e.g., resin material) over the top surface of the substrate 204 and the semiconductor devices 202. The encapsulant 206 can encase and protect the one or more semiconductor devices 202 from the external environment.

The assembly 200 can have external connectors (e.g., solder, pads, etc.) on a bottom surface of the substrate 204. The external connectors can be configured to provide electrical connections for communicating with external circuits, devices, or systems. Internally, the one or more semiconductor devices 202 can be electrically coupled to the substrate 204 using internal or die connectors 212. Some examples of the internal connectors 212 can include bond wires, solder, pads, pillars, or a combination thereof.

For each of the one or more semiconductor devices 202, the corresponding set of internal connectors 212 can be arranged according to a connector pitch 214. The connector pitch 214 can correspond to an actual separation distance between adjacently arranged connectors or a minimum/maximum threshold thereof. In some embodiments, such as for highspeed or higher performance devices, the one or more semiconductor devices 202 can have the connector pitch 214 that is less than a predetermined threshold (e.g., 500 μm, 300 μm or less) for accommodating the increased performance requirements.

The signals and voltages exchanged between the semiconductor devices 102 and/or with the external circuits can be routed through and/or across the substrate 204 using one or more RDLs therein. The RDLs can include contact pads 226a, traces 226b, wires, vias, signal planes, or a combination thereof. The RDLs can include electrically conductive metallic material, such as copper. One or more of the RDLs can be disposed between a reference layer 222 (e.g., a prepreg layer) and a solder resist layer 224. For example, the contact pads 226a and/or the traces 226b can be attached to a top surface of the reference layer 222, and the solder resist layer 224 can be over and/or directly contacting the contact pads 226a, the traces 226b, portions of the top surface of the reference layer 222, or a combination thereof.

The contact pads 226a can be configured to directly contact the internal connectors 212 for providing electrical connections to the corresponding devices 202. In some embodiments, the solder resist layer 224 can include openings directly over the contact pads 226a. The internal connectors 212 can extend through and occupy the openings, thereby directly contacting and attaching to the contact pads 226a.

In some embodiments, the internal connectors 212 can each include (1) a solder 234 over and contacting the contact pad 226a and (2) a pillar 232 (e.g., a copper extension) that extends from the die and directly contacts the solder 234. The different components within each of the internal connectors 212 can result from assembling the separately manufactured substrate 204 and semiconductor devices 202. For example, the substrate 204 may be manufactured or provided having the solder 234 over the contact pads 226a and in the corresponding openings. Separately, the semiconductor devices 202 may be manufactured or provided with the pillars 232 extending from a bottom or an active surface thereof. The semiconductor devices 202 can be subsequently mounted over the substrate 204 by aligning the pillars 232 with the corresponding solder 234 and then reflowing the solder 234. The internal connectors 212 can be formed based on reflowing the solder 234, thereby electrically connecting and affixing the pillars 232 to the solder 234 and to the substrate 204 overall.

Given the arrangement of the contact pads 226a (e.g., copper structure) between the solder resist layer 224 and the reference layer 222 and multiple reflows of the solder 234 during the manufacturing process, the assembly 200 can include a delamination reduction mechanism 250 (e.g., an adhesive) to increase the adhesion strength between the solder resist layer 224 and the reference layer 222. Accordingly, the delamination reduction mechanism 250 can reduce or prevent formation of the delamination 150 of FIG. 1B.

In some embodiments, the delamination reduction mechanism 250 can include an adhesion promoter. The adhesion promoter can include adhesives having properties that provide at least a threshold amount of adhesion strength to the solder resist layer 224, the reference layer 222, and the components within the RDL (e.g., copper structures). The threshold amount of adhesion strength for the adhesion promoter can be greater than the adhesion strength between the solder resist layer 224 and the components within the RDL.

The adhesion promoter (e.g., HexaMethylDiSilazane (HMDS)) can include material that have dual functionality in its molecular structure. For example, the adhesion promoter can include material having metallic central atom, such as silicon, zirconium, titanium, aluminum, or others, that have inorganic reactivity to the adhesion promoter when methoxy, ethoxy, or hydroxyl groups are attached to the metal atom. An organofunctional group can also be attached to the metal atom through an alkylene, arylene, or other type of organic bridge, to give traditional organic reactivity to the adhesion promoter.

The adhesion promoter can have an oligomeric structure based on the inorganic reactive groups condensing with themselves. The corresponding oligomeric adhesion promoter can have two or more functionalities and structural integrity, such that a stable chemical bond can occur between the dissimilar organic and inorganic surfaces (e.g., between metallic components and the solder resist layer 224) to promote adhesion between the two dissimilar materials.

As illustrated in FIG. 2B, the adhesion promoter can be disposed between and directly contacting the solder resist layer 224 and the RDL. For example, the adhesion promoter can provide an interface between the solder resist layer 224 can the metallic components (e.g., the copper structures) in the RDL, such as the traces 226b and the contact pads 226a. The adhesion promoter can reduce or eliminate direct contact between the metallic components and the solder resist layer 224. The adhesion promoter can additionally be disposed between and directly contact the solder resist layer 224 and the reference layer 222. In one or more embodiments, the adhesion promoter can cover or overlap the top/exposed surfaces of the reference layer 222 and the RDL thereon except for portions over the contact pads 226a that are exposed through the openings in the solder resist layer 224.

As described in further detail below, the adhesion promoter can be applied (1) below and contacting the solder resist layer, (2) over the RDL and a reference layer (e.g., a prepreg layer), and/or (3) before forming the openings in the solder resist layer 224 to accommodate the solder 234 during manufacturing of the assembly 200 or the substrate 204. Thus, in addition to enhancing the bonding strength of the solder resist layer 224 to the components there below, the delamination reduction mechanism 250 can be used to form more vertical and/or linear sidewalls 252 for the openings in the solder resist layer 224. In other words, the delamination reduction mechanism 250 can reduce or eliminate the formation of the mask undercuts 152 of FIG. 1B. The linear/vertical sidewalls 252 can result from the increased bond for the solder resist layer 224 relative to the contact pads 226a. During the formation of the openings (via, e.g., solder mask printing and/or etching), the increased bonding strength can reduce or eliminate the increased removal of the solder resist layer 224 that would otherwise occur (e.g., during manufacturing of the substrate 104 of 1B) at locations closer to and/or directly contacting the contact pads 226a. Based its physical shape, the resulting linear/vertical sidewalls 252 can reduce or eliminate the formation of the mask undercuts 152 that contribute to the delamination 150 by providing the upward lifting force during the reflow and hardening of the solder 234.

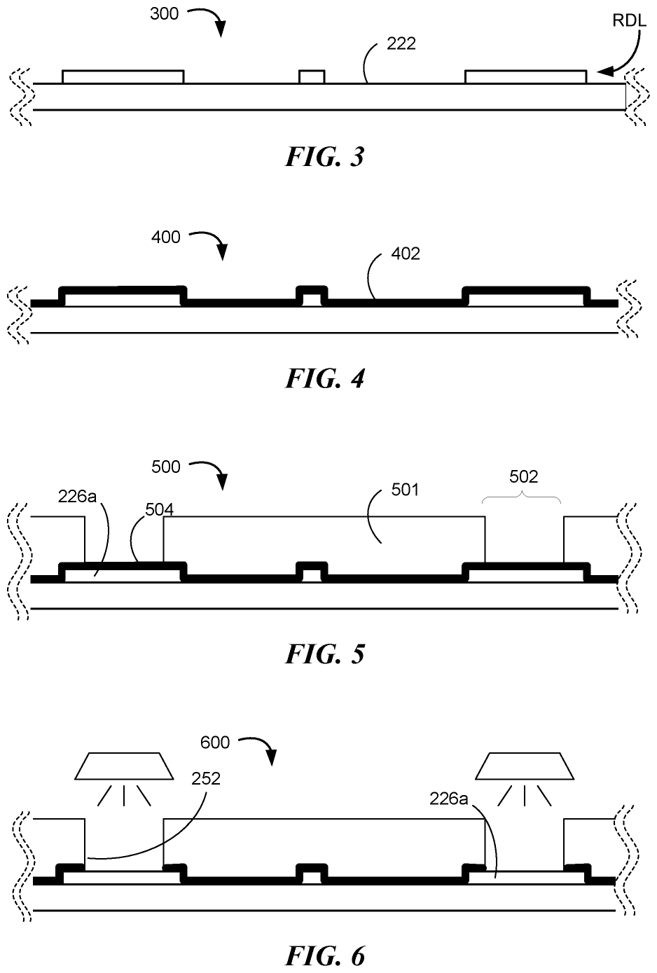

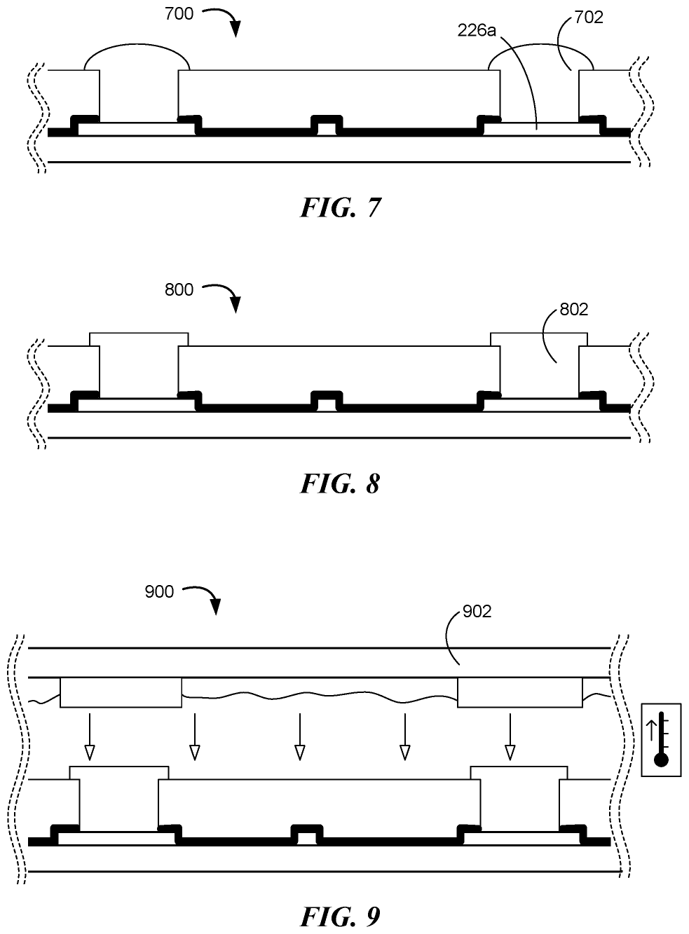

FIG. 3—FIG. 9 are example processing stages in manufacturing the semiconductor device assembly 200 of FIG. 2A or a portion thereof in accordance with an embodiment of the present technology. For example, FIG. 3-FIG. 8 can illustrate manufacturing of the substrate 204 of FIG. 2A having the delamination reduction mechanism 250 of FIG. 2B therein.

For the manufacturing process, FIG. 3 can illustrate a structure 300 resulting from patterning the RDL on the reference layer 222 (e.g., a prepreg layer). The reference layer 222 can be over other layers (e.g., core, other RDL layers, or the layer) that are not shown for the sake of brevity. The RDL, including the contact pads 226a and the traces 226b, may be patterned by forming electrically conductive structures, such as copper structures, at designated locations on the reference layer 222, such as by depositing metallic material and/or shaping (via, e.g., an etching process) the deposited metallic material.

FIG. 4 can illustrate a structure 400 resulting from applying a layer of adhesion promoter 402 over the structure 300 of FIG. 3. For example, the adhesion promoter, such as the HMDS or other similar material, can be coated with few microns on the components of the RDL, the reference layer 222 of FIG. 3, or a combination thereof.

FIG. 5 can illustrate a structure 500 resulting from printing the solder resist layer 224 of FIG. 2B at least partially over the components of the RDL. For example, a solder mask 501 may be coated or laminated over the structure 400 of FIG. 4. Accordingly, the solder mask 501 can directly contact the adhesion promoter 402. In comparison to the substrate 104 of FIG. 1B, the adhesion promoter 402 can reduce or eliminate direct contact between the solder mask and inorganic material, such as the metallic material (e.g., copper) patterned on the prepreg.

The structure 500 can further have contact openings 502 in the solder mask 501 to form the solder resist layer 224 of FIG. 2B. The contact openings 502 can be formed as a result of selectively depositing the solder mask. Alternatively or additionally, the contact openings 502 can be formed based on etching away portion of the solder mask over the contact pads 226a (via, e.g., photolithography and subsequent chemical, mechanical, and/or light-based etching). The resulting contact openings 502 can expose portions 504 of the adhesion promoter 402 of FIG. 4 over the contact pads 226a. The adhesion promoter 402 can have a different removal or etching mechanism than the solder mask. As such, the expose portions 504 of the adhesion promoter 402 can remain unaffected by the removing mechanism used to form the contact openings 502.

FIG. 6 can illustrate a structure 600 resulting from removing the expose portions 504 of the adhesion promoter 402 of FIG. 5 from the structure 500 of FIG. 5, such as through the contact openings 502 of FIG. 5. The remaining portion of the adhesion promoter 402 can correspond to the delamination reduction mechanism 250 of FIG. 2B.

In some embodiments, the expose portions 504 can be removed using chemical or dry etching process. As described above, the expose portions 504 can be removed using a mechanism that is different than the one used to form the contact openings 502. The removal of the expose portions 504 can further increase the roughness of the solder mask (e.g., a roughness on a top surface of the solder resist layer 224 of FIG. 2B), thereby further increasing the adhesion strength between the solder resist layer 224 and the encapsulant 206 of FIG. 2A.

Based on the sequence of processing steps illustrated in FIG. 4-FIG. 6, the structure 600 the adhesion promoter 402 can be used to form the vertical and/or linear sidewalls 252 for the openings 502 in the solder resist layer 224. Accordingly, the adhesion promoter 402 can reduce or eliminate the formation of the mask undercuts 152 of FIG. 1B as described above while exposing the contact pads 226a for subsequent electrical connections.

FIG. 7 illustrates a structure 700 resulting from applying solder material 702 on the contact pads 226a for the subsequent electrical connections. The solder material 702 can include electrically conductive material, such as an alloy (e.g., a combination of tin, lead, copper, silver, bismuth, and/or other similar metallic material), having a melting point lower than a threshold level. The solder material 702 can be applied within and occupy the contact openings 502 of FIG. 5. Accordingly, the solder material 702 can directly contact the contact pads 226a.

FIG. 8 illustrates a structure 800 resulting from shaping the solder material 702 of FIG. 7. For example, the structure 800 can result from solder coining to provide a solder structure 802 having a flat top surface configured to contact and interface with the pillars 232 of FIG. 2B. The coined solder material can correspond to the solder 234 of FIG. 2B. The structure 800 can correspond to the substrate 204 of FIG. 2B as separately manufactured and before it is attached to the semiconductor devices 202 of FIG. 2A.

FIG. 9 illustrates a processing step 900 for mounting a semiconductor device 902 over the structure 800 of FIG. 8. The semiconductor device 902 can represent one of the semiconductor devices 202 of FIG. 2 that is manufactured separately from the substrate 204. The semiconductor device 902 can have a die with the pillars 232 of FIG. 2B extending away from a bottom surface thereof. In some embodiments, the bottom surface and the pillars 232 can have the underfill 208 of FIG. 2A (e.g., a protective paste) applied thereon. In other embodiments, the underfill 208 can be flowed between the semiconductor device 902 and the structure 800 after they are mounted or affixed to each other.

The semiconductor device 902 can be mounted on the structure 800 based on first aligning the semiconductor device 902 over the structure 800 such that the pillars 232 overlap the corresponding instances of the solder 234 of FIG. 2B. The semiconductor device 902 can the structure 800 can be pressed to have the pillars 232 directly contacting the solder 234. Subsequently, the solder 234 can be reflowed, such as by temporarily increasing the temperature to or over the reflow threshold. In response the solder material can melt and then resolidify attached or bonded to the pillars 232 and the contact pads 262a of FIG. 2B. The resulting affixed combinations of the pillars 232 and the solder 234 can correspond to the internal connectors 212 of FIG. 2A. Accordingly, the semiconductor device 902 can be electrically connected and physically affixed to the substrate 204 using affixed combinations the pillars 232 and the solder 234. The resulting structure can correspond to the assembly 200 of FIG. 2.

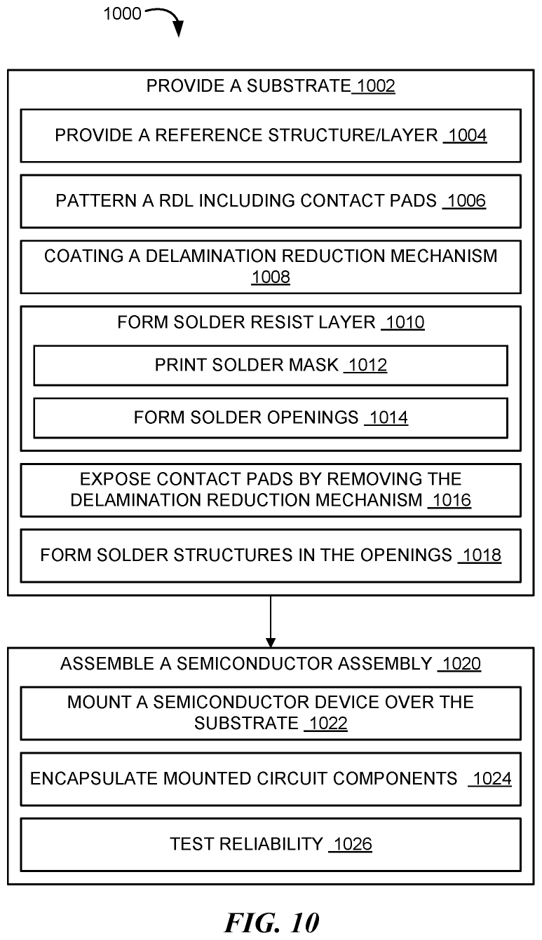

FIG. 10 is a flow diagram illustrating an example method 1000 of manufacturing a semiconductor device (e.g., the assembly 200 of FIG. 2A, the substrate 204 of FIG. 2A, or a portion thereof) in accordance with an embodiment of the present technology. The method 1000 can correspond to the processing stages illustrated in one or more of FIG. 3-FIG. 9.

The method 1000 can include providing a substrate (e.g., the substrate 204 of FIG. 2B). The provided substrate can include the delamination reduction mechanism 250 of FIG. 2B (e.g., an adhesion promoter) disposed between the solder resist layer 224 of FIG. 2B and the contact pads 226a of FIG. 2B (e.g., outer portions thereof) as described above. The delamination reduction mechanism 250 can have a dual functionality of bonding to the organic material in the solder resist layer 224 and the inorganic the contact pads 226a for improving the overall bonding strength between the solder resist layer 224 and the contact pads 226a over a direct bond between the two structures. Accordingly, the delamination reduction mechanism 250 can include material configured to bond with the polymer in the solder resist layer 224 and the metallic material in the contact pads 226a and provide respective bonding strengths that are greater than or exceeding a bonding strength associated with direct contact/bond between the corresponding polymer and metallic materials.

In some embodiments, the method 1000 can include manufacturing the substrate. In manufacturing the substrate, the method 1000 can include providing a reference structure/layer (e.g., the reference layer 222 of FIG. 2B) as illustrated at block 1004. The reference layer 222 can include a core (e.g., fiberglass or FR4) and/or one or more layers (e.g., polymer layers, signal distribution layers, or the like).

At block 1006, the method 1000 can include patterning a RDL including contact pads. The RDL can include metallic material, such as copper, alloy, or other similar electrically conductive material, patterned or coated over and/or directly on the reference layer 222 as described above with respect to FIG. 3. The patterned RDL can include the contact pads 226a.

At block 1008, the method 1000 can include coating a delamination reduction mechanism (e.g., the delamination reduction mechanism 250). For example, the delamination reduction mechanism can include the adhesion promoter coated over and/or directly on the contact pads 226a, the reference layer 222, or a combination thereof. The delamination reduction mechanism can be coated as described above with respect to FIG. 4.

At block 1010, the method 1000 can include forming a solder resist layer (e.g., the solder resist layer 224). For example, forming the solder resist layer can include printing or depositing the solder mask as illustrated at block 1012, forming solder openings (e.g., the contact openings 502 of FIG. 5) as illustrated at block 1014, or a combination thereof. The solder mask can be formed over and/or directly on the delamination reduction mechanism. The solder openings can be formed during the printing process and/or using an etching process to remove portions of the solder mask over the middle portions of the contact pads. As a result, the solder openings can have one or more vertical walls that extend from a top surface of the solder resist layer to the middle portions of the contact pads. The vertical walls can extend linearly along a vertical or an inward direction to the middle portions of the contact pads based on the increased bonding strength between the contact pad and the solder resist layer provided by the adhesion promoter disposed in between. The formation of the solder resist layer can correspond to the process described above with respect to FIG. 5.

At block 1016, the method 1000 can include exposing contact pads by removing corresponding portions of the delamination reduction mechanism. For example, the removal can correspond to removing the adhesion promoter through the solder opening using a etching process as described above with respect to FIG. 6.

At block 1018, the method 1000 can include forming solder structures in the openings. For example, the solder structures 802 of FIG. 8 can be formed by depositing and shaping solder material in the solder openings as described above with respect to FIG. 7 and FIG. 8.

At block 1020, the method 1000 can include assembling a semiconductor structure/assembly using the provided substrate. In manufacturing the assembly, the method 1000 can include mounting a semiconductor device (e.g., the semiconductor device 902 of FIG. 9) over the provided substrate (e.g., the structure 800 of FIG. 8) as illustrated at block 1022. The semiconductor device can be mounted as described above with respect to FIG. 9.

At block 1024, the method 1000 can include encapsulating the circuit components, such as by forming the encapsulant 206 of FIG. 2A. Also, at block 1026, the method 1000 can include testing the reliability of the assembled circuitry. The encapsulation and the reliability testing can include one or more processes that require a change of temperature that effectively reflows the solder. As described above, the delamination reduction mechanism 250 and the corresponding vertical walls in the solder openings (instead of the mask undercuts) can provide increased bonding strength between the solder resist layer 224 and the contact pads 226a and the reference layer 222. Accordingly, the delamination reduction mechanism 250 disposed between the solder resist layer 224 and the contact pads 226a (e.g., coated before forming the solder resist layer 224) can decrease occurrences of the delamination 150 of FIG. 1 and the corresponding structural and/or electrical failures.

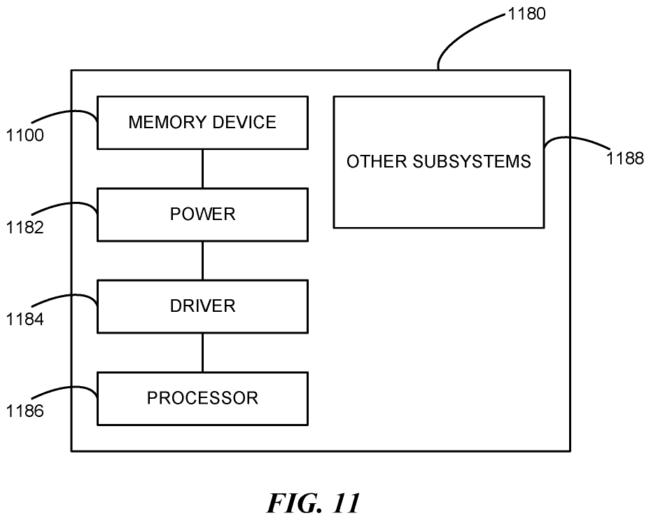

FIG. 11 is a schematic view of a system that includes an apparatus in accordance with embodiments of the present technology. Any one of the foregoing apparatuses (e.g., memory devices) described above with reference to FIGS. 1-10 can be incorporated into any of a myriad of larger and/or more complex systems, a representative example of which is system 1180 shown schematically in FIG. 11. The system 1180 can include a memory device 1100, a power source 1182, a driver 1184, a processor 1186, and/or other subsystems or components 1188. The memory device 1100 can include features generally similar to those of the apparatus described above with reference to FIGS. 1-10, and can therefore include various features for performing a direct read request from a host device. The resulting system 1180 can perform any of a wide variety of functions, such as memory storage, data processing, and/or other suitable functions. Accordingly, representative systems 1180 can include, without limitation, hand-held devices (e.g., mobile phones, tablets, digital readers, and digital audio players), computers, vehicles, appliances and other products. Components of the system 1180 may be housed in a single unit or distributed over multiple, interconnected units (e.g., through a communications network). The components of the system 1180 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-11.

I/We claim:

1. A semiconductor memory device assembly, comprising:
a printed circuit board (PCB) including:
a reference layer;
a contact pad over the reference layer, wherein the contact pad includes metallic material for electrically coupling the PCB to a circuit device mounted thereon;
a solder resist layer over the reference layer and peripheral portions of the contact pad, the solder resist layer including a solder opening exposing a middle portion of the contact pad;
a delamination reduction mechanism disposed between the solder resist layer and the peripheral portions of the contact pad, wherein the delamination reduction mechanism has bonding strengths relative to the solder resist layer and the contact pad that are greater than a bonding strength between the metallic material of the contact pad and the solder resist layer; and
solder directly contacting the exposed middle portion of the contact pad and within the solder opening; and
a semiconductor device mounted on the PCB, the semiconductor device including a connector portion extending from a bottom surface of the semiconductor device and electrically coupled and affixed to the solder.

2. The assembly of claim 1, wherein the delamination reduction mechanism is an adhesion promoter configured to have a dual functionality for attaching to both organic and inorganic materials.

3. The assembly of claim 2, wherein:
the reference layer is a prepreg layer;
the contact pad includes copper;
the solder resist layer includes polymer material; and
the adhesion promoter is configured for attaching to both the copper and the polymer materials.

4. The assembly of claim 2, wherein the adhesion promoter and the solder resist layer have different mechanisms for removing and shaping the corresponding materials.

5. The assembly of claim 1, wherein the PCB includes a set of contact pads, including the contact pad, for coupling with the semiconductor device, wherein the set of contact pads are arranged according to a pitch corresponding to a maximum lateral separation distance between adjacent contact pads, wherein the maximum lateral separation distance is 500 μm.

6. The assembly of claim 1, wherein the solder opening is defined by one or more walls that extend continuously and linearly between a top surface of the solder resist layer and the contact pad.

7. The assembly of claim 6, wherein the continuous and linear walls are characteristic of having the delamination reduction mechanism disposed between the contact pad and the solder resist layer before formation of the solder opening for reducing occurrences of a mask undercut that provides a lifting force on the solder resist layer and away from the contact pad during solder reflow.

8. The assembly of claim 1, further comprising:
a trace over and extending laterally across at least a portion of the reference layer, the trace electrically coupled to the contact pad and configured to route one or more signals to and/or from the contact pad to one or more other circuits, wherein the delamination reduction mechanism is a layer disposed between and directly contacting the solder resist layer and a combination of the reference layer, a portion of the contact pad, and the trace.

9. The assembly of claim 1, wherein the delamination reduction mechanism is disposed between the solder resist layer and the contact pad at the solder opening for reducing a likelihood of delamination of the solder resist layer from the reference layer based on increasing a relative bonding strength between the solder resist layer and the contact pad at the solder opening that experiences pressure during reflowing of the solder.

10. A substrate, comprising
a reference layer;
a set of contact pads over the reference layer, wherein the contact pads are configured to electrically couple the substrate to one or more corresponding circuit devices mounted thereon;
a solder resist layer over and covering the reference layer and peripheral portions of the contact pads, the solder resist layer including solder openings exposing middle portions of the contact pads;
a delamination reduction mechanism disposed between the solder resist layer and the peripheral portions of the contact pads, wherein the delamination reduction mechanism has bonding strengths to the solder resist layer and the contact pad that exceed a bonding strength between the contact pads and the solder resist layer; and
solder directly contacting the exposed middle portions of the contact pads and within the solder openings.

11. The substrate of claim 10, wherein:
the substrate is a printed circuit board (PCB);
the contact pads include metallic material;
the solder resist layer includes polymer material; and
the delamination reduction mechanism is an adhesion promoter configured to have a dual functionality for attaching to both an organic material in the polymer material and an inorganic material in the metallic material to increase an overall bonding strength between the solder resist layer and the contact pads.

12. The substrate of claim 11, wherein the contact pads are arranged according to a pitch corresponding to a maximum lateral separation distance between adjacent contact pads, wherein the maximum lateral separation distance is 500 μm.

13. The substrate of claim 10, wherein each of the solder openings is defined by one or more walls that extend from a top surface of the solder resist layer to a corresponding one of the middle portions of the contact pads.

14. The substrate of claim 13, wherein the one or more walls for the each of the solder openings extends vertically or inwardly toward the corresponding one of the middle portions of the contact pads.

15. The substrate of claim 14, wherein the one or more walls are characteristic of having the delamination reduction mechanism disposed between the contact pad and the solder resist layer before formation of the solder openings for reducing occurrences of mask undercuts that extend downward and laterally away from the middle portions of the contact pads and the corresponding lifting forces on the solder resist layer during solder reflow.

16. A method of manufacturing a semiconductor device, the method comprising:
providing a substrate that includes:
a reference layer;
a contact pad over the reference layer, wherein the contact pad includes metallic material for electrically coupling the PCB to a circuit device mounted thereon;
a solder resist layer over the reference layer and peripheral portions of the contact pad, the solder resist layer including a solder opening exposing a middle portion of the contact pad;
an adhesion promoter disposed between the solder resist layer and the peripheral portions of the contact pad, wherein the adhesion promoter has bonding strengths relative to the solder resist layer and the contact pad that are greater than a bonding strength between the metallic material of the contact pad and the solder resist layer; and
solder directly contacting the exposed middle portion of the contact pad and within the solder opening; and
mounting a semiconductor device on the PCB, the semiconductor device including a connector portion extending from a bottom surface of the semiconductor device and electrically coupled and affixed to the solder.

17. The method of claim 16, wherein the adhesion promoter has a dual functionality for attaching to both organic and inorganic materials.

18. The method of claim 16, wherein providing the substrate includes:
providing the reference layer having the contact pad thereon;
coating the adhesion promoter over the contact pad and the reference layer;
forming the solder resist layer over the adhesion promoter, wherein the solder mask includes the solder opening exposing the middle portion of the contact pad;
exposing the middle portion of the contact pad based on removing a corresponding portion of the adhesion promoter through the solder opening; and
depositing the solder in the solder opening.

19. The method of claim 18, wherein forming the solder resist layer over the adhesion promoter includes forming one or more vertical walls that extend linearly from a top surface of the solder resist layer to the middle portion of the contact pad, wherein the one or more vertical walls are formed based on (1) depositing solder mask and (2) etching away portion thereof.

20. The method of claim 19, wherein forming the one or more vertical walls includes forming the one or more vertical walls that extend linearly and inwardly based on the increased bonding strength between the contact pad and the solder resist layer provided by the adhesion promoter in between.
